(19) United States
(12) Patent Application Publication
(10) Pub. No.: US 2025/0324709 A1
(43) Pub. Date: Oct. 16, 2025

(54) SEMICONDUCTOR DEVICE AND METHOD FOR MANUFACTURING SAME

(71) Applicants: Kabushiki Kaisha Toshiba, Tokyo (JP); Toshiba Electronic Devices & Storage Corporation, Tokyo (JP)

(72) Inventors: Hiroko ITOKAZU, Kawasaki Kanagawa (JP); Keiko KAWAMURA, Yokohama Kanagawa (JP); Yoko IWAKAJI, Meguro Tokyo (JP); Hidenobu KOJIMA, Kanazawa Ishikawa (JP); Kazuki MINAMIKAWA, Nomi Ishikawa (JP)

(21) Appl. No.: 18/892,092

(22) Filed: Sep. 20, 2024

(30) Foreign Application Priority Data
Apr. 10, 2024 (JP) 2024-063551

(51) Int. Cl. H01L 29/417; H01L 29/40; H01L 29/66; H01L 29/739

(52) U.S. Cl. CPC H10D 64/231; H10D 12/038; H10D 12/481; H10D 64/01

(57) ABSTRACT

A semiconductor device according to an embodiment includes: a first electrode including a first metal layer, a second metal layer, and an insulator; a second electrode; a semiconductor layer provided between the first electrode and the second electrode; and an insulating layer provided between the first electrode and the semiconductor layer, wherein the first electrode includes a first portion electrically connecting the semiconductor layer and the first electrode, the first portion is provided between one part of the insulating layer and another part of the insulating layer in a cross section parallel to a first direction connecting the first electrode and the second electrode, and the first portion includes the first metal layer in contact with the semiconductor layer, the second metal layer, and the insulator provided between the first metal layer and the second metal layer.

### CROSS-REFERENCE TO RELATED APPLICATION

This application is based upon and claims the benefit of priority from Japanese Patent Application No. 2024-063551, filed on Apr. 10, 2024, the entire contents of which are incorporated herein by reference.

### FIELD

Embodiments described herein relate generally to a semiconductor device and a method for manufacturing the semiconductor device.

### BACKGROUND

As an example of power semiconductor devices, there is a vertical power semiconductor device in which electrodes are provided above and below a semiconductor layer. When a power semiconductor device is manufactured using a semiconductor wafer, the semiconductor wafer may be warped due to stress caused by a metal film.

### BRIEF DESCRIPTION OF THE DRAWINGS

FIGS. 1A and 1B are schematic diagrams of a semiconductor device according to a first embodiment;

FIG. 2 is a schematic cross-sectional view of a part of the semiconductor device according to the first embodiment;

FIG. 3 is an enlarged schematic cross-sectional view of the semiconductor device according to the first embodiment;

FIG. 4 is a view for explanation of a method for manufacturing the semiconductor device according to the first embodiment;

FIG. 5 is a diagram for explanation of a method for manufacturing the semiconductor device according to the first embodiment;

FIG. 6 is a diagram for explanation of a method for manufacturing the semiconductor device according to the first embodiment;

FIG. 7 is a diagram for explanation of a method for manufacturing the semiconductor device according to the first embodiment;

FIG. 8 is a diagram for explanation of a method for manufacturing the semiconductor device according to the first embodiment;

FIG. 9 is a schematic cross-sectional view of a part of a semiconductor device according to a first comparative example;

FIG. 10 is a schematic cross-sectional view of a part of a semiconductor device according to a second comparative example;

FIG. 11 is a schematic cross-sectional view of a part of a semiconductor device according to a first modified example of the first embodiment;

FIG. 12 is a schematic cross-sectional view of a part of a semiconductor device according to a second modified example of the first embodiment;

FIGS. 13A and 13B are schematic diagrams of a semiconductor device according to a second embodiment;

FIG. 14 is a schematic cross-sectional view of a part of the semiconductor device according to the second embodiment;

FIG. 15 is a view for explanation of a method for manufacturing the semiconductor device according to the second embodiment;

FIG. 16 is a schematic cross-sectional view of a part of a semiconductor device according to a modified example of the second embodiment;

FIGS. 17A and 17B are schematic diagrams of a semiconductor device according to a third embodiment;

FIG. 18 is a schematic cross-sectional view of a part of the semiconductor device according to the third embodiment; and

FIG. 19 is a view for explanation of a method for manufacturing the semiconductor device according to the third embodiment.

### DETAILED DESCRIPTION

A semiconductor device according to an embodiment includes: a first electrode including a first metal layer, a second metal layer, and an insulator; a second electrode; a semiconductor layer provided between the first electrode and the second electrode; and an insulating layer provided between the first electrode and the semiconductor layer, wherein the first electrode includes a first portion electrically connecting the semiconductor layer and the first electrode, the first portion is provided between one part of the insulating layer and another part of the insulating layer in a cross section parallel to a first direction connecting the first electrode and the second electrode, and the first portion includes the first metal layer in contact with the semiconductor layer, the second metal layer, and the insulator provided between the first metal layer and the second metal layer.

Hereinafter, embodiments of the present disclosure will be described with reference to the drawings. In the following description, the same or similar members and the like are denoted by the same reference numerals, and the description of the members and the like once described shall be appropriately omitted.

In the present specification, when there are notations of n⁺ type, n type, and n⁻ type, it means that an n type impurity concentration decreases in the order of n⁺ type, n type, and n⁻ type. In addition, when there are notations of p⁺ type, p type, and p⁻ type, it means that the p type impurity concentration decreases in the order of p⁺ type, p type, and p⁻ type.

Qualitative analyses and quantitative analyses of chemical compositions of members constituting the semiconductor device in the present specification can be performed by, for example, secondary ion mass spectrometry (SIMS), energy dispersive X-ray spectroscopy (EDX), and Rutherford backscattering spectrometry (Rutherford Back-Scattering Spectroscopy: RBS). In addition, for example, a transmission electron microscope (TEM) can be used for measuring thicknesses of the members constituting the semiconductor device, distances between the members, and the like.

### First Embodiment

A semiconductor device according to a first embodiment includes a first electrode having a first metal layer, a second metal layer, and an insulator, a second electrode, a semiconductor layer provided between the first electrode and the second electrode, and an insulating layer provided between the first electrode and the semiconductor layer. The first electrode includes a first portion electrically connecting the semiconductor layer and the first electrode. The first portion is provided between one part of the insulating layer and another part of the insulating layer in a cross section parallel to a first direction connecting the first electrode and the second electrode. The first portion includes the first metal layer in contact with the semiconductor layer, the second metal layer, and the insulator provided between the first metal layer and the second metal layer.

The semiconductor device of the first embodiment is an insulated gate bipolar transistor (IGBT) 100. The IGBT 100 is a trench gate type IGBT including a gate electrode in a trench formed in a semiconductor layer.

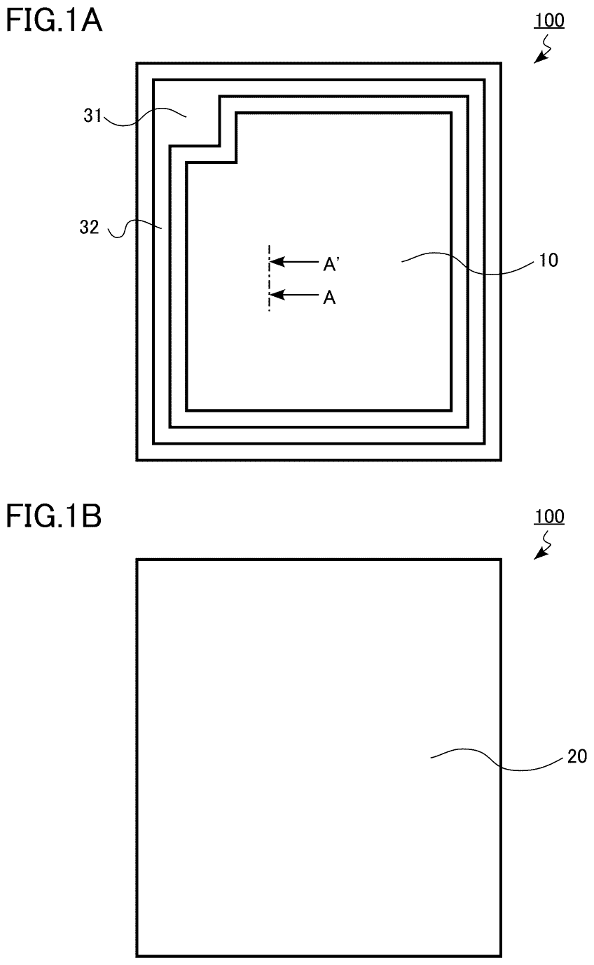

FIGS. 1A and 1B are schematic diagrams of the semiconductor device of the first embodiment. FIG. 1A is a front side view of the IGBT 100. FIG. 1B is a rear side view of the IGBT 100.

As illustrated in FIG. 1A, an emitter electrode 10, a gate electrode pad 31, and a gate electrode wiring 32 are provided on a front surface side of the IGBT 100. The gate electrode wiring 32 is connected to the gate electrode pad 31.

As illustrated in FIG. 1B, a collector electrode 20 is provided on a back surface side of the IGBT 100.

A plurality of transistors is provided under the emitter electrode 10. The gate electrode pad 31 and the gate electrode wiring 32 are electrically connected to the gate electrodes of the transistor. A gate voltage for controlling a switching operation of the transistors is applied to the gate electrode pad 31.

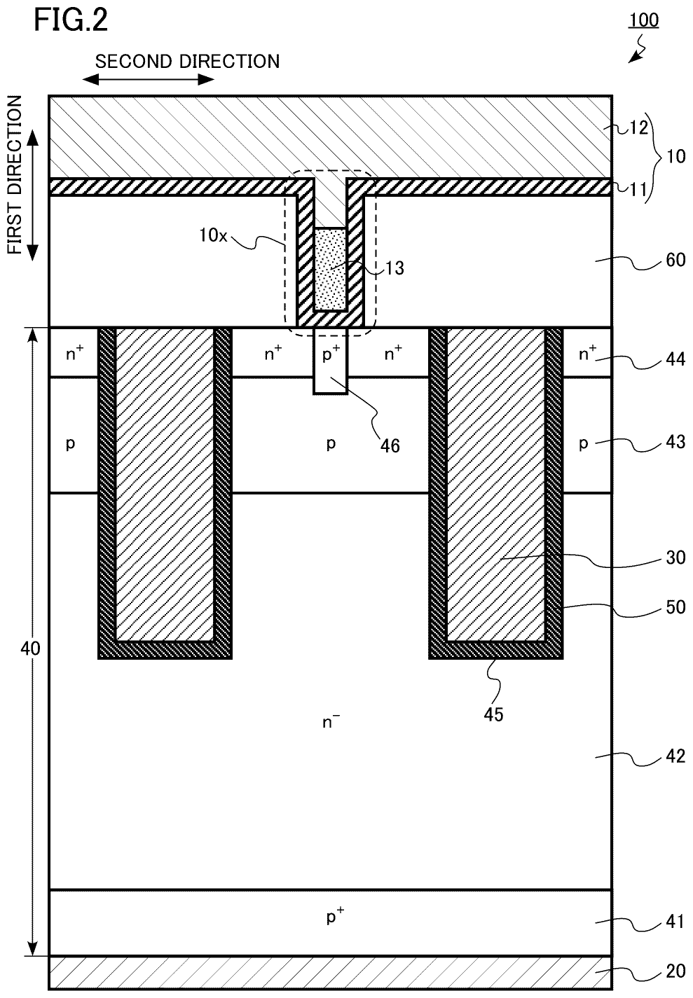

FIG. 2 is a schematic cross-sectional view of a part of the semiconductor device according to the first embodiment. FIG. 2 is a cross section taken along line AA′ in FIG. 1A.

The IGBT 100 according to the first embodiment includes the emitter electrode 10 (first electrode), the collector electrode 20 (second electrode), the gate electrode 30, a semiconductor layer 40, a gate insulating film 50, and an interlayer insulating layer 60 (insulating layer).

The emitter electrode 10 includes a first metal layer 11, a second metal layer 12, and an insulator 13. The emitter electrode 10 includes a contact portion 10x (first portion).

In the semiconductor layer 40, a collector region 41, a drift region 42, a base region 43, an emitter region 44, and a contact region 46 are provided. A gate trench 45 is provided for the semiconductor layer 40.

Hereinafter, a direction connecting the emitter electrode 10 and the collector electrode 20 is referred to as a first direction. The first direction is a normal direction of a surface of the semiconductor layer 40. A direction orthogonal to the first direction is referred to as a second direction.

The semiconductor layer 40 is provided between the emitter electrode 10 and the collector electrode 20. The semiconductor layer 40 is in contact with the emitter electrode 10 and the collector electrode 20.

The semiconductor layer 40 is, for example, single crystal silicon. A thickness of the semiconductor layer 40 is, for example, equal to or more than 40 μm and equal to or less than 700 μm.

The collector region 41 is a p⁺ type semiconductor region. The collector region 41 is electrically connected to the collector electrode 20. The collector region 41 is in contact with the collector electrode 20. The collector region 41 serves as a supply source of holes when the IGBT 100 is in an ON state.

The drift region 42 is an n⁻ type semiconductor region. The drift region 42 is provided on the collector region 41.

The drift region 42 serves as a path of an on-current when the IGBT 100 is in the ON state. The drift region 42 has a function of being depleted when the IGBT 100 is in the OFF state to maintain a breakdown voltage of the IGBT 100.

The base region 43 is a p type semiconductor region. The base region 43 is provided on the drift region 42.

A depth of the base region 43 is, for example, equal to or less than 5 μm. In an area in the base region 43, the area facing the gate electrode 30, an n type inversion layer is formed when the IGBT 100 is in the ON state. The base region 43 serves as a channel region of the IGBT 100.

The emitter region 44 is an n⁺ type semiconductor region. The emitter region 44 is provided on the base region 43.

The emitter region 44 is in contact with the gate trench 45. The emitter region 44 is in contact with the gate insulating film 50.

The emitter region 44 is in contact with the contact portion 10x of the emitter electrode 10. The emitter region 44 is electrically connected to the emitter electrode 10. The emitter region 44 serves as a supply source of electrons when the IGBT 100 is in the ON state.

The contact region 46 is a p⁺ type semiconductor region. The contact region 46 is provided on the base region 43.

The contact region 46 is in contact with the contact portion 10x of the emitter electrode 10. The contact region 46 is electrically connected to the emitter electrode 10. The contact region 46 electrically connects the emitter electrode 10 and the base region 43.

Here, the contact region 46 may not necessarily be provided at a position sandwiched between the emitter regions 44 in the second direction. The contact region 46 may be provided, for example, in a depth direction in FIG. 2 with respect to the emitter region 44.

The gate trench 45 is provided on a side of the emitter electrode 10 of the semiconductor layer 40. The gate trench 45 is a groove provided in the semiconductor layer 40. The gate trench 45 is a part of the semiconductor layer 40.

The gate trench 45 penetrates the emitter region 44 and the base region 43 and reaches the drift region 42. The gate trench 45 is in contact with the emitter region 44, the base region 43, and the drift region 42.

The gate electrode 30 is provided in the gate trench 45. The gate electrode 30 is electrically connected to the gate electrode wiring 32 and the gate electrode pad 31.

The gate electrode 30 is a conductor. The gate electrode 30 is, for example, a semiconductor or a metal. The gate electrode 30 is, for example, amorphous silicon containing conductive impurities or polycrystalline silicon containing conductive impurities.

The gate insulating film 50 is provided between the gate electrode 30 and the semiconductor layer 40. The gate insulating film 50 is provided between the gate electrode 30 and the drift region 42, between the gate electrode 30 and the base region 43, and between the gate electrode 30 and the emitter region 44. The gate insulating film 50 is provided between the emitter electrode 10 and the semiconductor layer 40.

The gate insulating film 50 is an insulating body. The gate insulating film 50 is, for example, silicon oxide.

The interlayer insulating layer 60 is provided between the semiconductor layer 40 and the emitter electrode 10. The interlayer insulating layer 60 is provided between the gate electrode 30 and the emitter electrode 10. The interlayer insulating layer 60 is an insulating body. The interlayer insulating layer 60 is, for example, silicon oxide.

The emitter electrode 10 is provided above the semiconductor layer 40. The emitter electrode 10 is provided on the interlayer insulating layer 60.

The emitter electrode 10 includes the first metal layer 11, the second metal layer 12, and the insulator 13. The second metal layer 12 is provided on the first metal layer 11. The first metal layer 11 is provided, for example, between the interlayer insulating layer 60 and the second metal layer 12.

The emitter electrode 10 includes the contact portion 10x. The contact portion 10x electrically connects the emitter electrode 10 and the semiconductor layer 40.

The contact portion 10x is in contact with the semiconductor layer 40. The contact portion 10x is in contact with, for example, the emitter region 44.

The contact portion 10x is provided between a part of the interlayer insulating layer 60 and another part of the interlayer insulating layer 60 in a cross section parallel to the first direction, for example, in the cross section illustrated in FIG. 2. In FIG. 2, the interlayer insulating layer 60 on the left side of the contact portion 10x corresponds to the part of the interlayer insulating layer 60, and the interlayer insulating layer 60 on the right side of the contact portion 10x corresponds to the another part of the interlayer insulating layer 60.

The contact portion 10x exists in an opening provided in the interlayer insulating layer 60. A bottom surface of the contact portion 10x is in contact with the semiconductor layer 40. A side surface of the contact portion 10x is in contact with the interlayer insulating layer 60.

The contact portion 10x includes the first metal layer 11, the second metal layer 12, and the insulator 13.

In the contact portion 10x, the first metal layer 11 is in contact with the semiconductor layer 40. In the contact portion 10x, the first metal layer 11 is in contact with, for example, the emitter region 44.

In the contact portion 10x, the insulator 13 is provided between the first metal layer 11 and the second metal layer 12. The insulator 13 is in contact with, for example, the first metal layer 11 and the second metal layer 12. The insulator 13 is surrounded by the first metal layer 11 and the second metal layer 12 in a cross section parallel to the first direction.

The first metal layer 11 is a conductor. The first metal layer contains, for example, a metal or a metal compound. The first metal layer contains at least one metal element selected from the group consisting of titanium (Ti), tantalum (Ta), nickel (Ni), tungsten (W), and molybdenum (Mo).

The second metal layer 12 is a conductor. The chemical composition of the second metal layer 12 is different from the chemical composition of the first metal layer 11, for example.

The second metal layer 12 contains, for example, a metal or a metal compound. The first metal layer contains, for example, aluminum (Al) or copper (Cu).

The insulator 13 is an insulating body. The insulator 13 includes, for example, an oxide, a nitride, or an oxynitride. The insulator 13 includes, for example, silicon oxide, silicon nitride, or silicon oxynitride.

The collector electrode 20 is provided under the semiconductor layer 40. The collector electrode 20 is in contact with the collector region 41.

The collector electrode 20 is a conductor. The collector electrode 20 contains, for example, a metal or a metal compound.

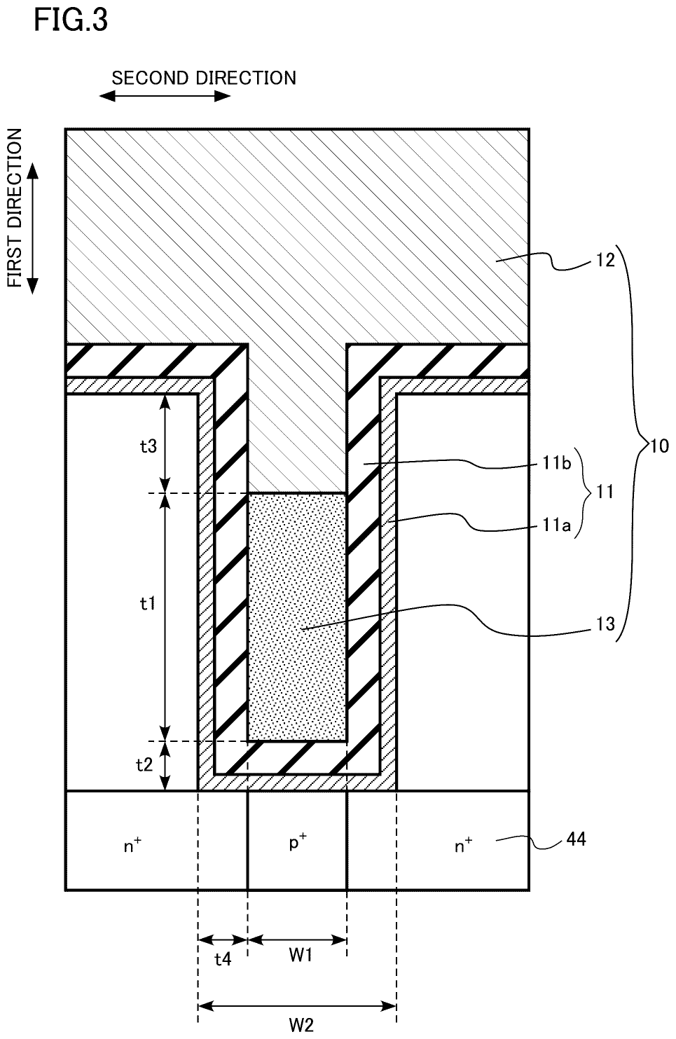

FIG. 3 is an enlarged schematic cross-sectional view of the semiconductor device according to the first embodiment. FIG. 3 is an enlarged view of a part of FIG. 2. FIG. 3 is a diagram including the contact portion 10x of the emitter electrode 10.

As illustrated in FIG. 3, the first metal layer 11 has a stacked structure of, for example, a first film 11a and a second film 11b. The first film 11a contains, for example, a metal nitride. The first film 11a is, for example, a stacked film of a single-component metal film and a metal nitride film. The second film 11b includes, for example, a single-component metal.

The first film 11a is, for example, a stacked film of a titanium film and a titanium nitride film. The second film 11b is, for example, a tungsten film.

In the cross section parallel to the first direction, for example, a first thickness (t1 in FIG. 3) of the insulator 13 of the contact portion 10x in the first direction is thicker than a second thickness (t2 in FIG. 3) of the first metal layer 11 of the bottom surface of the contact portion 10x in the first direction. The first thickness t1 is, for example, equal to or more than 2 times and equal to or less than 20 times of the second thickness t2.

In the cross section parallel to the first direction, for example, the first thickness t1 of the insulator 13 of the contact portion 10x in the first direction is larger than a first width (W1 in FIG. 3) of the insulator 13 of the contact portion 10x in the second direction. The first thickness t1 is, for example, equal to or more than 1.5 times and equal to or less than 10 times of the first width W1. Here, the first width W1 may not necessarily coincide with the width of the contact region 46 in the second direction as illustrated in FIG. 3.

In the cross section parallel to the first direction, for example, the first width W1 of the insulator 13 of the contact portion 10x in the second direction is equal to or more than ½ and equal to or less than 9/10 of a second width (W2 in FIG. 3) of the contact portion 10x in the second direction.

In the cross section parallel to the first direction, for example, a third thickness (t3 in FIG. 3) of the second metal layer 12 of the contact portion 10x in the first direction is thicker than the second thickness t2 of the first metal layer 11 of the bottom surface of the contact portion 10x in the first direction. The third thickness t3 is, for example, equal to or more than 1.5 times and equal to or less than 20 times of the second thickness t2.

In the cross section parallel to the first direction, for example, the second thickness t2 of the first metal layer 11 of the bottom surface of the contact portion 10x in the first direction is substantially equal to a fourth thickness (t4 in FIG. 3) of the first metal layer 11 of the side surface of the contact portion 10x in the second direction.

Next, an example of a method for manufacturing the semiconductor device according to the first embodiment will be described.

The method for manufacturing the semiconductor device according to the first embodiment includes: forming a first insulating film on a first layer that is a semiconductor layer; defining an opening in the first insulating film; forming a first metal film in an interior of the opening, the first metal film being in contact with the first layer; forming a second insulating film on the first metal film, the second insulating film filling the interior of the opening; removing the second insulating film around the opening; and forming a second metal film on the first metal film, the second metal film being in contact with the first metal film and the second insulating film.

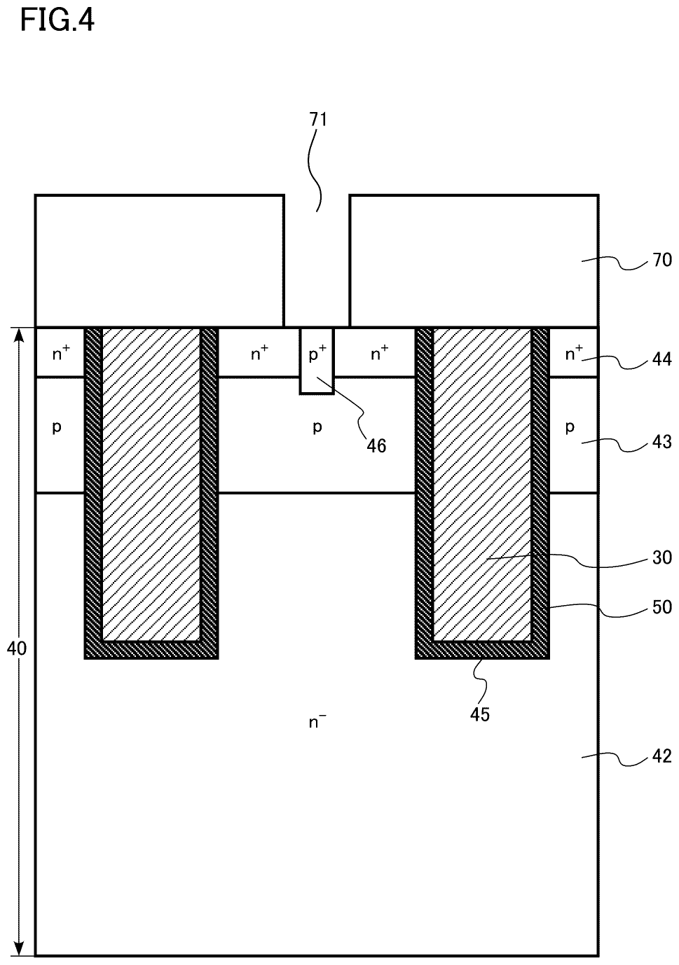

FIGS. 4, 5, 6, 7, and 8 are diagrams for explanation of the method for manufacturing the semiconductor device of the first embodiment. FIGS. 4 to 8 are cross-sectional views corresponding to FIG. 2 of the first embodiment.

First, the drift region 42, the base region 43, the emitter region 44, the contact region 46, and the gate trench 45 are formed in the semiconductor layer 40 using a known process technology. Next, the gate insulating film 50 and the gate electrode 30 are formed using a known process technology. The semiconductor layer 40 is an example of the first layer.

Next, a first silicon oxide film 70 is formed on the surface of the semiconductor layer 40. The first silicon oxide film 70 is formed by, for example, a chemical vapor deposition method (CVD method). The first silicon oxide film 70 is an example of the first insulating film. The first silicon oxide film 70 becomes the interlayer insulating layer 60 in the end.

Next, an opening 71 is defined in the first silicon oxide film 70 (FIG. 4). The opening 71 reaches the semiconductor layer 40. The semiconductor layer 40 is exposed at a bottom of the opening 71. The opening 71 is defined by using, for example, a lithography method and a reactive-ion etching method (RIE method).

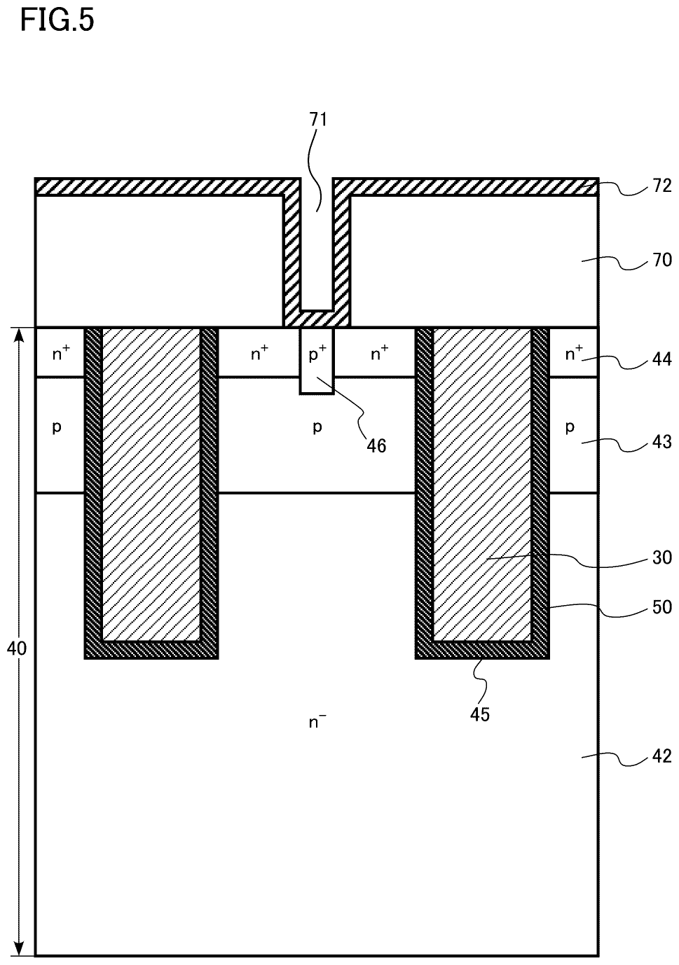

Next, a stacked film 72 of titanium and titanium nitride is formed (FIG. 5). The stacked film 72 is in contact with the semiconductor layer 40 in the opening 71.

The stacked film 72 is formed by, for example, a CVD method. The stacked film 72 is an example of the first metal film. The stacked film 72 becomes the first metal layer 11 in the end.

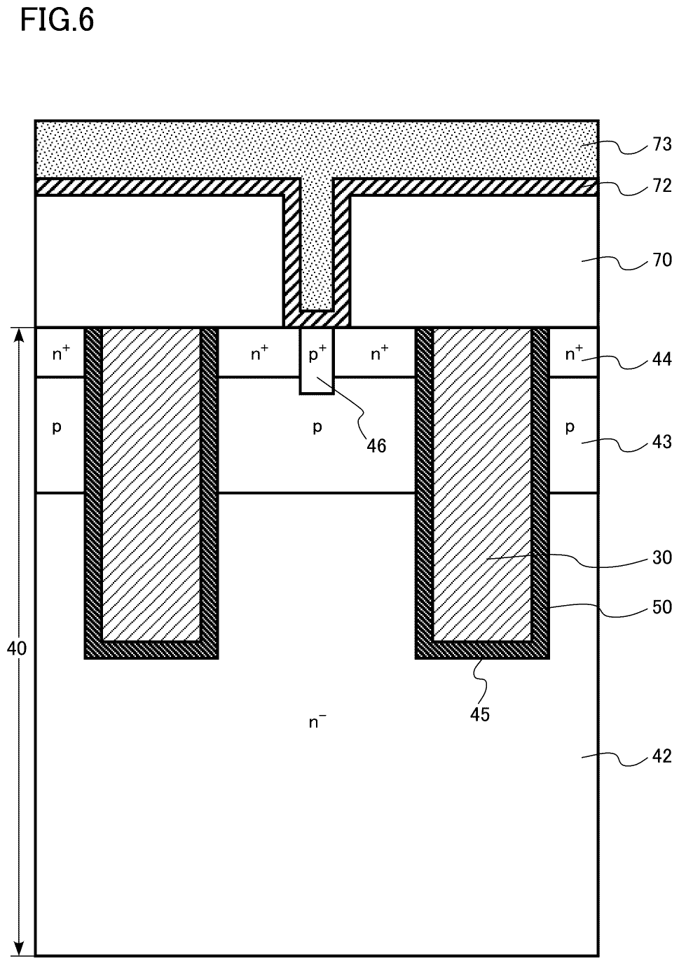

Next, a second silicon oxide film 73 is formed on the stacked film 72 (FIG. 6). The second silicon oxide film 73 fills the opening 71.

The second silicon oxide film 73 is formed by, for example, a CVD method. The second silicon oxide film 73 is an example of the second insulating film. A part of the second silicon oxide film 73 becomes the insulator 13 in the end.

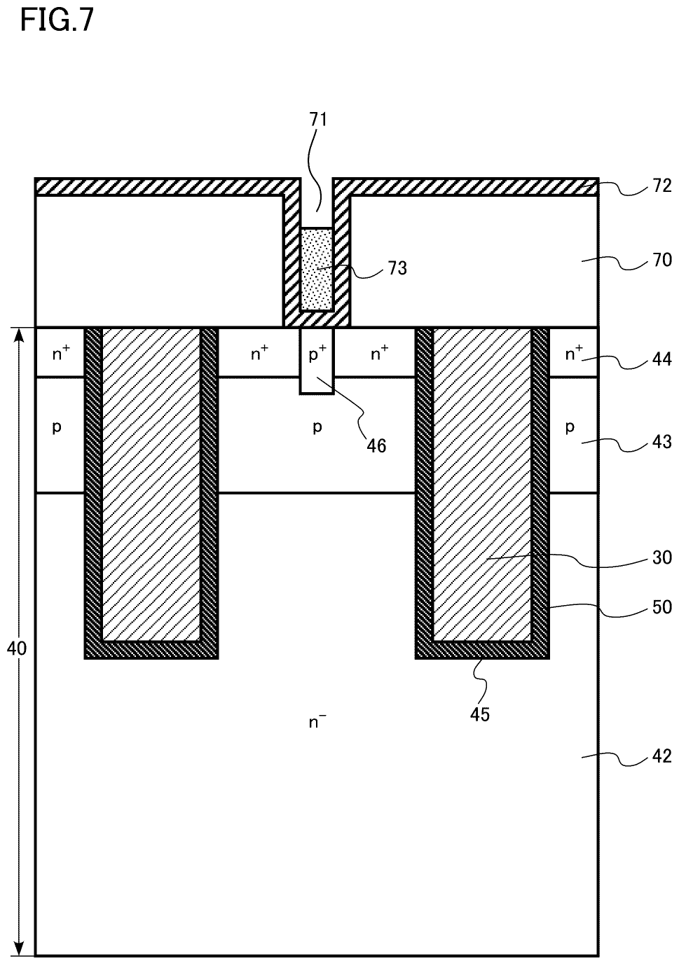

Next, the second silicon oxide film 73 around the opening 71 is removed (FIG. 7). The second silicon oxide film 73 on the stacked film 72 around the opening 71 is removed. A part of the second silicon oxide film 73 remains in the opening 71.

The second silicon oxide film 73 is removed by, for example, an RIE method.

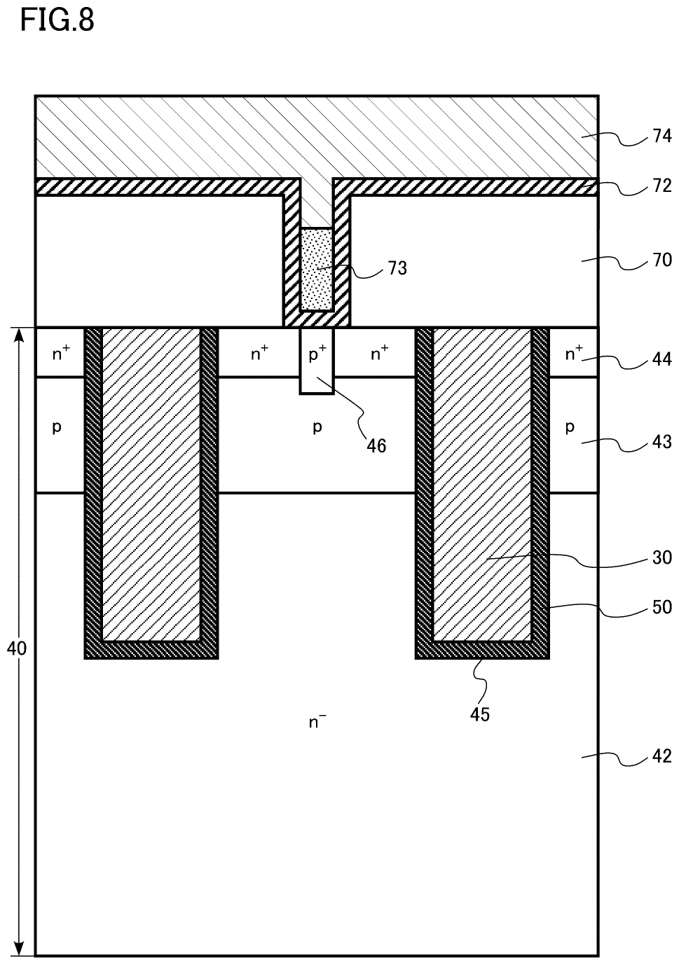

Next, an aluminum film 74 is formed on the stacked film 72 (FIG. 8). The aluminum film 74 is in contact with the stacked film 72 and the second silicon oxide film 73 in the opening 71.

The aluminum film 74 is formed by, for example, a sputtering method. The aluminum film 74 is an example of the second metal film. The aluminum film 74 becomes the second metal layer 12 in the end.

Thereafter, the collector region 41 and the collector electrode 20 are formed on a back surface side of the semiconductor layer 40 using a known process technology.

The IGBT 100 of the first embodiment illustrated in FIG. 2 is manufactured according to the above method for manufacturing the semiconductor device.

Next, functions and effects of the semiconductor device and a method for manufacturing the semiconductor device according to the first embodiment will be described.

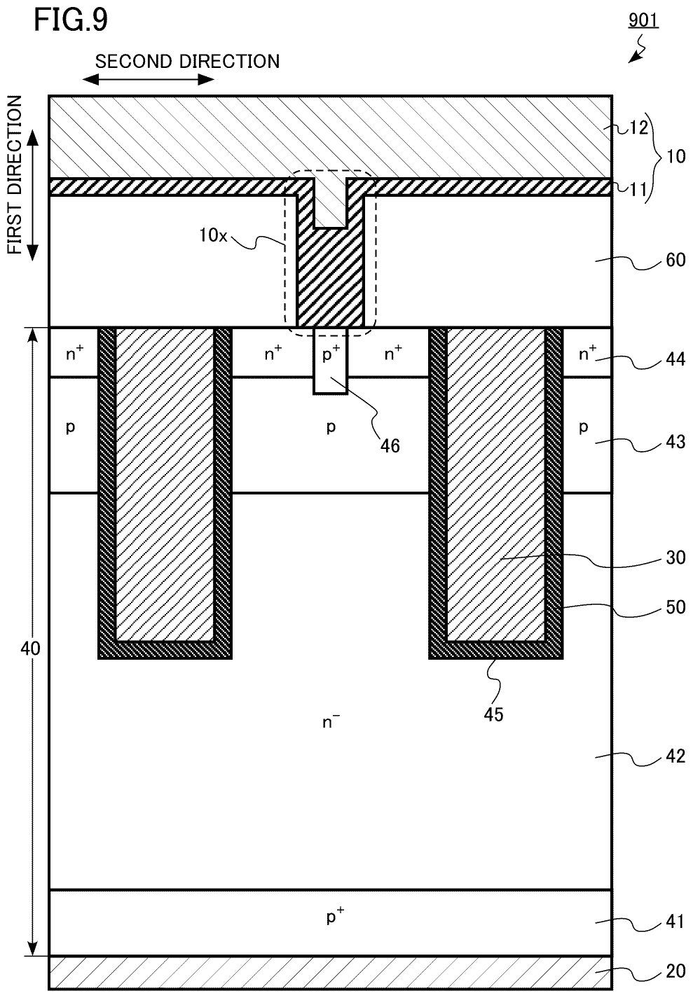

FIG. 9 is a schematic cross-sectional view of a part of a semiconductor device according to a first comparative example. FIG. 9 is a diagram corresponding to FIG. 2 of the first embodiment.

An IGBT 901 of the first comparative example is different from the IGBT 100 of the first embodiment in that the contact portion 10x does not include the insulator 13.

In the IGBT 901, the contact portion 10x is embedded with the first metal layer 11 and the second metal layer 12. A stress of a metal material in which the contact portion 10x is embedded may cause warpage in the semiconductor wafer. When the semiconductor wafer is warped, it is difficult to manufacture the IGBT 901.

In the IGBT 100 of the first embodiment, the contact portion 10x is embedded with the insulator 13 instead of the metal material. Since the contact portion 10x is embedded with the insulator 13, the stress caused by the metal material is reduced. Therefore, warpage of the semiconductor wafer is suppressed.

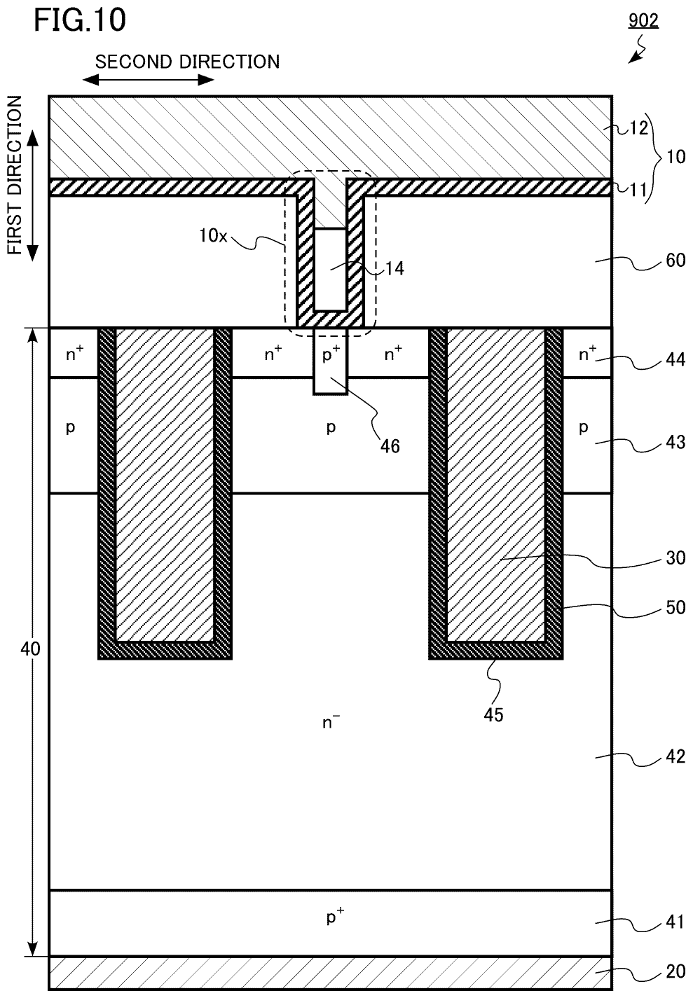

FIG. 10 is a schematic cross-sectional view of a part of a semiconductor device according to a second comparative example. FIG. 10 is a diagram corresponding to FIG. 2 of the first embodiment.

An IGBT 902 of the second comparative example is different from the IGBT 100 of the first embodiment in that the contact portion 10x does not include the insulator 13 and a cavity 14 (Void) is present instead.

In the IGBT 902, a crack may occur from the cavity 14 of the contact portion 10x during, for example, an operation of the IGBT 902. Further, in the IGBT 902, for example, there is a risk that an aluminum film sinks into the cavity 14 and a crack occurs. The crack generated in the IGBT 902 lowers reliability of the IGBT 902.

In the IGBT 100 of the first embodiment, the cavity 14 does not exist in the contact portion 10x, and is filled with the insulator 13. Therefore, a mechanical strength of the contact portion 10x is improved, an occurrence of cracks is suppressed, and reliability of the IGBT 100 is improved.

In the cross section parallel to the first direction, the first thickness (t1 in FIG. 3) of the insulator 13 of the contact portion 10x in the first direction is preferably thicker than the second thickness (t2 in FIG. 3) of the first metal layer 11 of the bottom surface of the contact portion 10x in the first direction. Since the first thickness t1 is larger than the second thickness t2, the stress caused by the metal material is relaxed.

### First Modified Example

A semiconductor device according to a first modified example of the first embodiment is different from the semiconductor device according to the first embodiment in that a part of a side surface of the first portion is in contact with the semiconductor layer in a cross section parallel to the first direction.

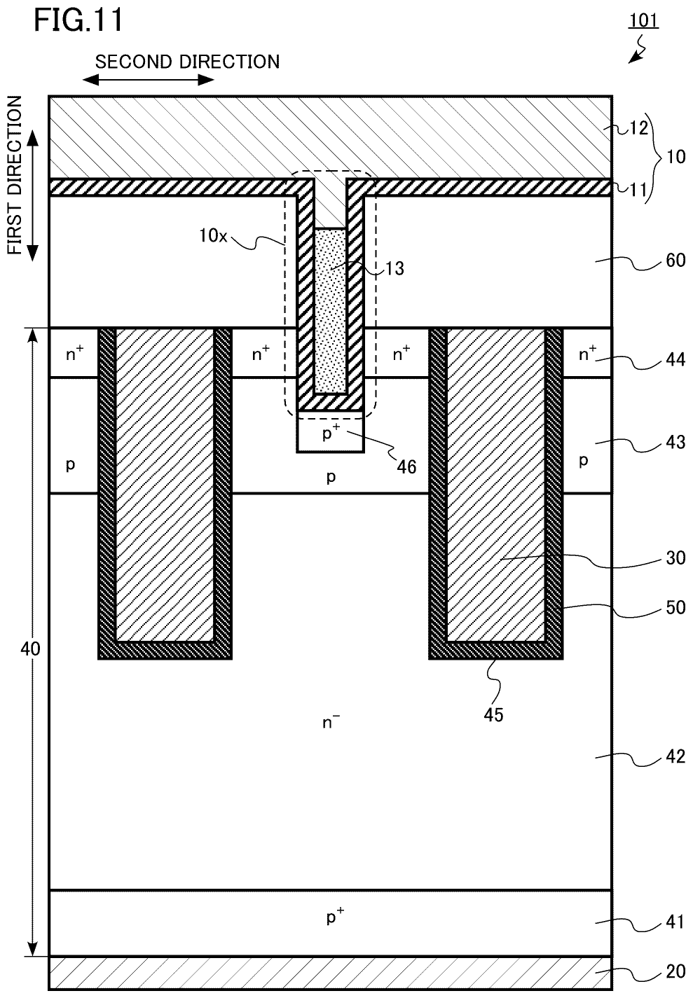

FIG. 11 is a schematic cross-sectional view of a part of the semiconductor device according to the first modified example of the first embodiment. FIG. 11 is a diagram corresponding to FIG. 2 of the first embodiment.

In an IGBT 101 of the first modified example, a part of the side surface of the contact portion 10x is in contact with the semiconductor layer 40 in the cross section parallel to the first direction. The side surface of the contact portion 10x is in contact with, for example, the interlayer insulating layer 60, the emitter region 44, and the base region 43. The bottom surface of the contact portion 10x is in contact with, for example, the contact region 46.

The IGBT 101 of the first modified example can be manufactured, for example, in the method for manufacturing the semiconductor device of the first embodiment described above, by etching the semiconductor layer 40 when the opening 71 is defined in the first silicon oxide film 70 and then forming the contact region 46 using an ion implantation method.

### Second Modified Example

A semiconductor device according to a second modified example of the first embodiment is different from the semiconductor device according to the first embodiment in that, in a cross section parallel to the first direction, a second thickness of the first metal layer of a bottom surface of the first portion in the first direction is thicker than a fourth thickness of a side surface of the first portion in the second direction.

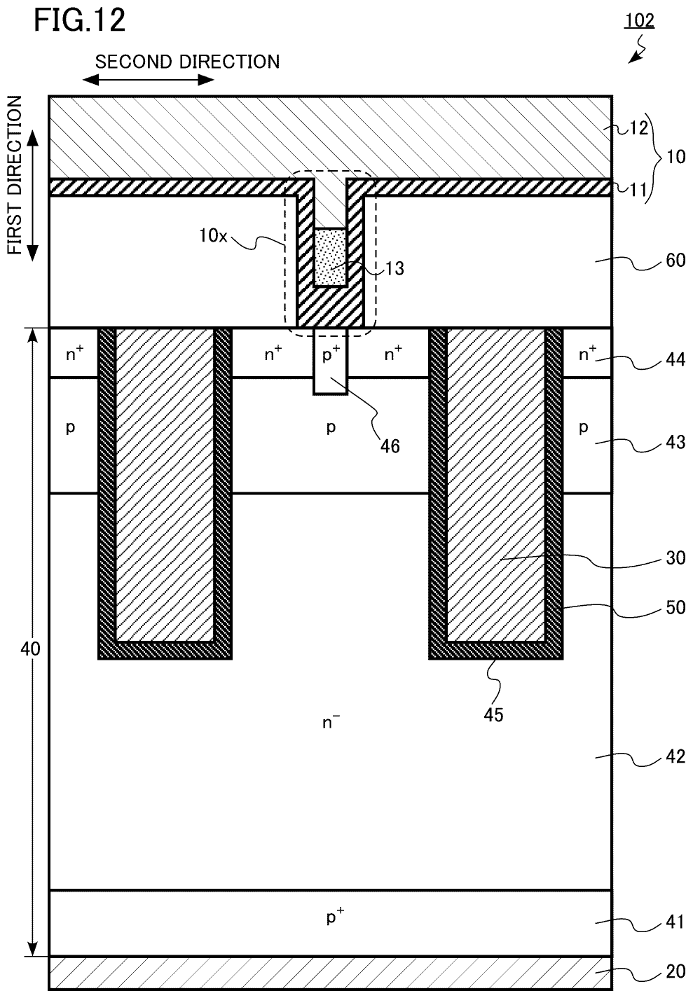

FIG. 12 is a schematic cross-sectional view of a part of the semiconductor device according to the second modified example of the first embodiment. FIG. 12 is a diagram corresponding to FIG. 2 of the first embodiment.

An IGBT 102 of the second modified example is configured such that in the cross section parallel to the first direction, for example, the second thickness t2 (t2 in FIG. 3) of the first metal layer 11 of the bottom surface of the contact portion 10x in the first direction is thicker than the fourth thickness (t4 in FIG. 3) of the first metal layer 11 of the side surface of the contact portion 10x in the second direction.

The IGBT 102 of the second modified example can be manufactured, for example, in the method for manufacturing the semiconductor device of the first embodiment described above, by forming the stacked film 72 under the condition that a thickness deposited on the bottom of the opening 71 is thicker than a thickness deposited on sidewalls.

According to the IGBT 102 of the second modified example, for example, an electric resistance of the contact portion 10x can be reduced.

As described above, according to the semiconductor device and the method for manufacturing the semiconductor device of the first embodiment and the modified example, it is possible to realize the semiconductor device that suppresses the warpage of the semiconductor wafer.

### Second Embodiment

A semiconductor device according to a second embodiment includes: a first electrode including a first metal layer, a second metal layer, and an insulator; a second electrode; a semiconductor layer provided between the first electrode and the second electrode; a first insulating layer provided between the first electrode and the semiconductor layer; a second insulating layer provided between the first insulating layer and the first electrode; and a conductive layer provided between the first insulating layer and the second insulating layer. The first electrode includes a first portion connecting the conductive layer and the first electrode. The first portion is provided between one part of the second insulating layer and another part of the second insulating layer in a cross section parallel to a first direction connecting the first electrode and the second electrode. The first portion includes the first metal layer in contact with the conductive layer, the second metal layer, and the insulator provided between the first metal layer and the second metal layer. The semiconductor device according to the second embodiment is different from the semiconductor device according to the first embodiment in that the first portion connects the conductive layer and the first electrode. Hereinafter, descriptions of contents overlapping with the first embodiment may be partially omitted.

The semiconductor device of the second embodiment is an IGBT 200. The IGBT 200 is a trench gate type IGBT including a gate electrode in a trench formed in a semiconductor layer.

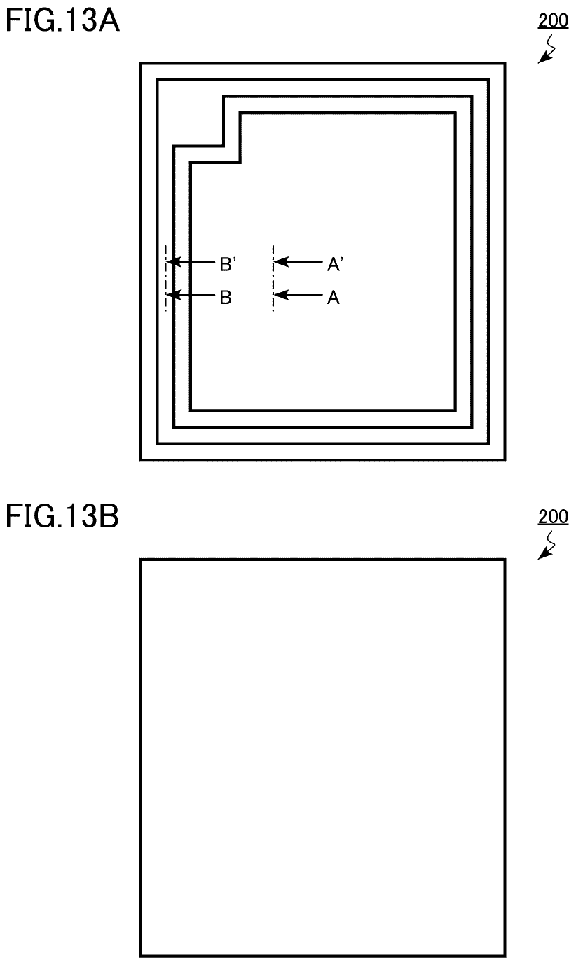

FIGS. 13A and 13B are schematic diagrams of the semiconductor device of the second embodiment. FIG. 13A is a front side view of the IGBT 200. FIG. 13B is a rear side view of the IGBT 200.

As illustrated in FIG. 13A, an emitter electrode 10, a gate electrode pad 31, and a gate electrode wiring 32 are provided on a front surface side of the IGBT 200. The gate electrode wiring 32 is connected to the gate electrode pad 31.

As illustrated in FIG. 13B, a collector electrode 20 is provided on a back surface side of the IGBT 200.

A plurality of transistors is provided under the emitter electrode 10. The gate electrode pad 31 and the gate electrode wiring 32 are electrically connected to the gate electrodes of the transistor. A gate voltage for controlling a switching operation of the transistors is applied to the gate electrode pad 31.

In the AA′ cross section of FIG. 13A, the IGBT 200 has, for example, the same structure as the IGBT 100 of the first embodiment shown in FIG. 2.

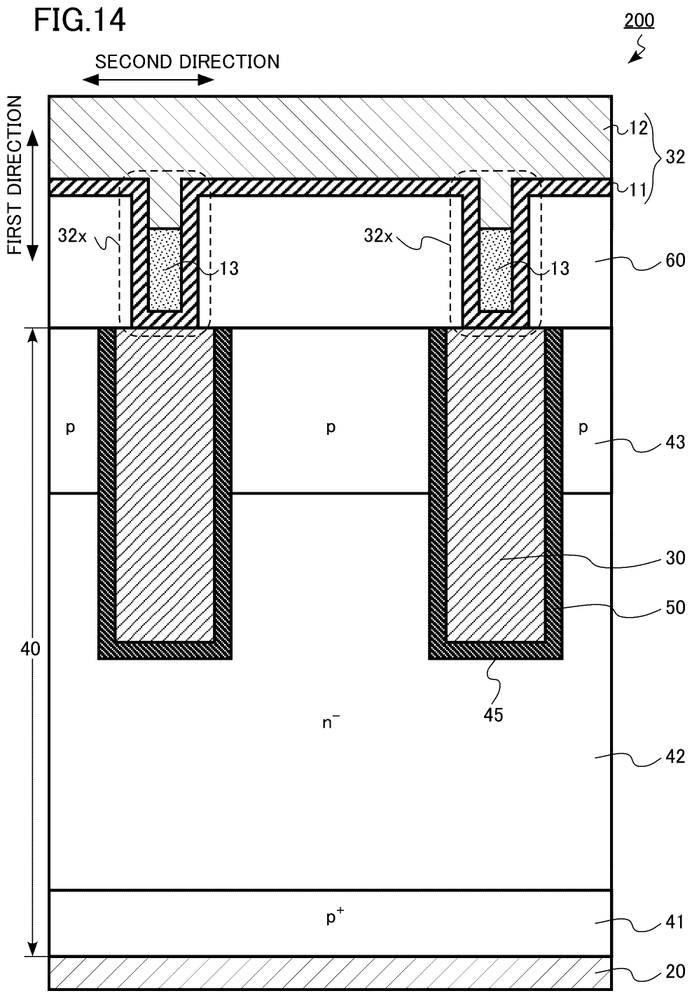

FIG. 14 is a schematic cross-sectional view of a part of the semiconductor device according to the second embodiment. FIG. 14 is a cross section taken along line BB′ in FIG. 13A.

The IGBT 200 according to the second embodiment includes the collector electrode 20 (second electrode), the gate electrode 30 (conductive layer), the gate electrode wiring 32 (first electrode), the semiconductor layer 40, the gate insulating film 50 (first insulating layer), and the interlayer insulating layer 60 (second insulating layer).

The gate electrode wiring 32 includes the first metal layer 11, the second metal layer 12, and the insulator 13. The gate electrode wiring 32 includes a contact portion 32x (first portion).

In the semiconductor layer 40, the collector region 41, the drift region 42, and the base region 43 are provided. The gate trench 45 (trench) is provided for the semiconductor layer 40.

Hereinafter, a direction connecting the gate electrode wiring 32 and the collector electrode 20 is referred to as the first direction. A direction orthogonal to the first direction is referred to as a second direction.

The semiconductor layer 40 is provided between the gate electrode wiring 32 and the collector electrode 20. The semiconductor layer 40 is in contact with the collector electrode 20.

The gate trench 45 is provided on a side of the gate electrode wiring 32 of the semiconductor layer 40. The gate trench 45 is a groove provided in the semiconductor layer 40. The gate trench 45 is a part of the semiconductor layer 40.

The gate trench 45 penetrates the base region 43 and reaches the drift region 42. The gate trench 45 is in contact with the base region 43 and the drift region 42.

The gate electrode 30 is provided in the gate trench 45. The gate electrode 30 is provided between the gate insulating film 50 and the interlayer insulating layer 60. The gate electrode 30 is electrically connected to the gate electrode wiring 32 and the gate electrode pad 31. The gate electrode 30 is an example of the conductive layer.

The gate electrode 30 is a conductor. The gate electrode 30 is, for example, a semiconductor or a metal. The gate electrode 30 is, for example, amorphous silicon containing conductive impurities or polycrystalline silicon containing conductive impurities.

The gate insulating film 50 is provided between the gate electrode 30 and the semiconductor layer 40. The gate insulating film 50 is provided between the gate electrode 30 and the drift region 42, and between the gate electrode 30 and the base region 43. The gate insulating film 50 is provided between the gate electrode wiring 32 and the semiconductor layer 40. The gate insulating film 50 is an example of the first insulating layer.

The gate insulating film 50 is an insulating body. The gate insulating film 50 is, for example, silicon oxide.

The interlayer insulating layer 60 is provided between the semiconductor layer 40 and the gate electrode wiring 32. The interlayer insulating layer 60 is provided between the gate insulating film 50 and the gate electrode wiring 32. The interlayer insulating layer 60 is provided between the gate electrode 30 and the gate electrode wiring 32. The interlayer insulating layer 60 is an example of the second insulating layer.

The interlayer insulating layer 60 is an insulating body. The interlayer insulating layer 60 is, for example, silicon oxide.

The gate electrode wiring 32 is provided above the semiconductor layer 40. The gate electrode wiring 32 is provided on the interlayer insulating layer 60.

The gate electrode wiring 32 includes the first metal layer 11, the second metal layer 12, and the insulator 13. The second metal layer 12 is provided on the first metal layer 11. The first metal layer 11 is provided, for example, between the interlayer insulating layer 60 and the second metal layer 12.

The gate electrode wiring 32 includes the contact portion 32x. The contact portion 32x electrically connects the gate electrode wiring 32 and the gate electrode 30. The contact portion 32x is in contact with the gate electrode 30.

The contact portion 32x is provided between a part of the interlayer insulating layer 60 and another part of the interlayer insulating layer 60 in the cross section parallel to the first direction, for example, in the cross section illustrated in FIG. 14. In FIG. 14, the interlayer insulating layer 60 on the left side of the contact portion 32x corresponds to the part of the interlayer insulating layer 60, and the interlayer insulating layer 60 on the right side of the contact portion 32x corresponds to the another part of the interlayer insulating layer 60.

The contact portion 32x exists in an opening provided in the interlayer insulating layer 60. A bottom surface of the contact portion 32x is in contact with the gate electrode 30. A side surface of the contact portion 32x is in contact with the interlayer insulating layer 60.

The contact portion 32x includes the first metal layer 11, the second metal layer 12, and the insulator 13.

In the contact portion 32x, the first metal layer 11 is in contact with the gate electrode 30.

In the contact portion 32x, the insulator 13 is provided between the first metal layer 11 and the second metal layer 12. The insulator 13 is in contact with, for example, the first metal layer 11 and the second metal layer 12. The insulator 13 is surrounded by the first metal layer 11 and the second metal layer 12 in a cross section parallel to the first direction.

The first metal layer 11 is a conductor. The first metal layer contains, for example, a metal or a metal compound. The first metal layer contains at least one metal element selected from the group consisting of titanium (Ti), tantalum (Ta), nickel (Ni), tungsten (W), and molybdenum (Mo).

The second metal layer 12 is a conductor. The chemical composition of the second metal layer 12 is different from the chemical composition of the first metal layer 11, for example.

The second metal layer 12 contains, for example, a metal or a metal compound. The first metal layer contains, for example, aluminum (Al) or copper (Cu).

The insulator 13 is an insulating body. The insulator 13 includes, for example, an oxide, a nitride, or an oxynitride. The insulator 13 includes, for example, silicon oxide, silicon nitride, or silicon oxynitride.

The contact portion 32x has the same structure as the contact portion 10x of the first embodiment illustrated in FIG. 3 except that the bottom surface of the contact portion 32x is in contact with the gate electrode 30 instead of the semiconductor layer 40.

Next, an example of a method for manufacturing the semiconductor device according to the second embodiment will be described.

The method for manufacturing the semiconductor device according to the second embodiment includes: forming a first insulating film on a first layer that is a conductive layer; defining an opening in the first insulating film; forming a first metal film in an interior of the opening, the first metal film being in contact with the first layer; forming a second insulating film on the first metal film, the second insulating film filling the interior of the opening; removing the second insulating film around the opening; and forming a second metal film on the first metal film, the second metal film being in contact with the first metal film and the second insulating film. The method for manufacturing the semiconductor device according to the second embodiment is different from the method for manufacturing the semiconductor device according to the first embodiment in that the first layer is not a semiconductor layer but a conductive layer. Hereinafter, description of contents overlapping with those of the first embodiment will be omitted.

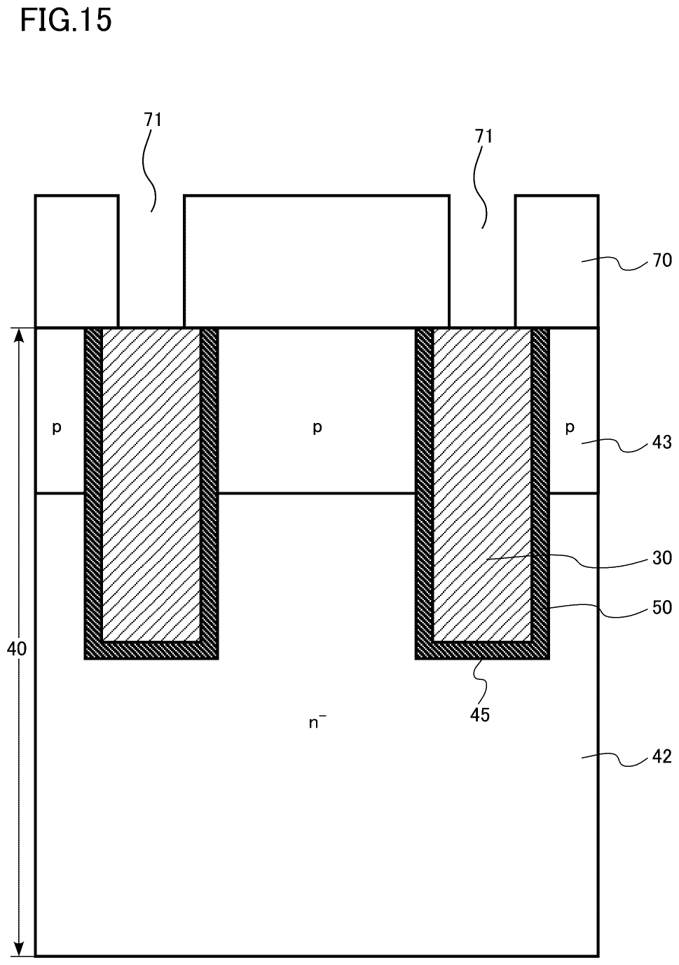

FIG. 15 is a view for explanation of the method for manufacturing the semiconductor device according to the second embodiment. FIG. 15 is a cross-sectional view corresponding to FIG. 14 of the second embodiment.

First, the drift region 42, the base region 43, and the gate trench 45 are formed in the semiconductor layer 40 using a known process technology. Next, the gate insulating film 50 and the gate electrode 30 are formed using a known process technology.

The gate electrode 30 is a conductive layer. The gate electrode 30 is an example of the first layer.

Next, the first silicon oxide film 70 is formed on the surfaces of the semiconductor layer 40 and the gate electrode 30. The first silicon oxide film 70 is formed by, for example, a chemical vapor deposition method (CVD method). The first silicon oxide film 70 is an example of the first insulating film. The first silicon oxide film 70 becomes the interlayer insulating layer 60 in the end.

Next, the opening 71 is defined in the first silicon oxide film 70 (FIG. 15). The opening 71 reaches the gate electrode 30. The gate electrode 30 is exposed at the bottom of the opening 71. The opening 71 is defined by using, for example, a lithography method and a reactive-ion etching method (RIE method).

After the opening 71 is defined, the IGBT 200 of the second embodiment illustrated in FIG. 14 is manufactured by a manufacturing method similar to the method for manufacturing the semiconductor device of the first embodiment.

### Modified Example

A semiconductor device according to a modified example of the second embodiment is different from the semiconductor device according to the second embodiment in that a part of a side surface of the first portion is in contact with the conductive layer in a cross section parallel to the first direction.

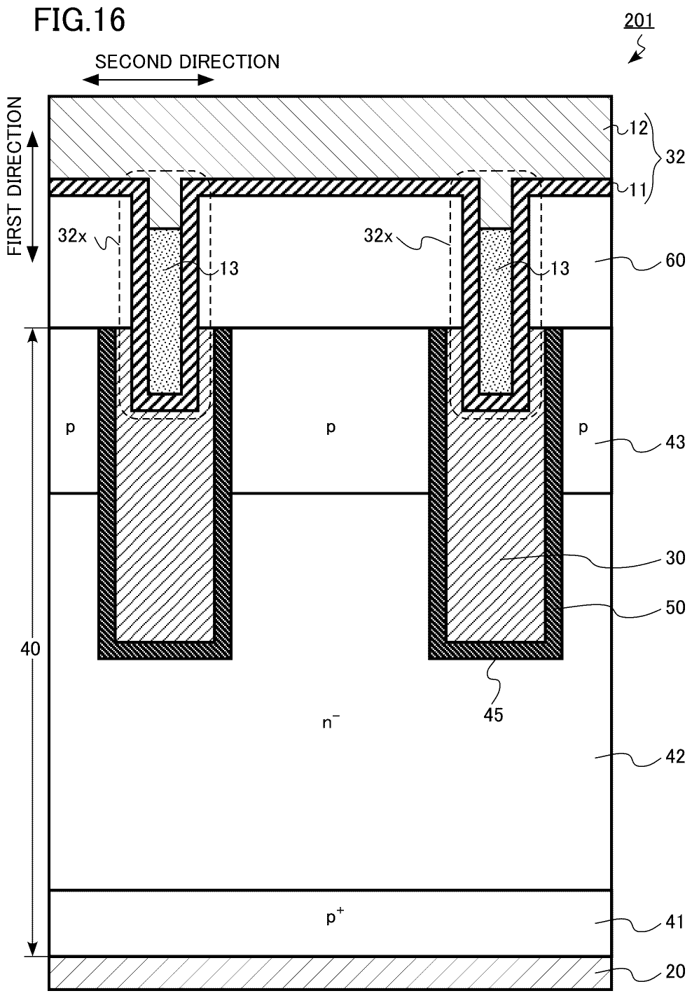

FIG. 16 is a schematic cross-sectional view of a part of a semiconductor device according to a modified example of the second embodiment. FIG. 16 is a diagram corresponding to FIG. 14 of the second embodiment.

In an IGBT 201 of the modified example, a part of the side surface of the contact portion 32x is in contact with the gate electrode 30 in the cross section parallel to the first direction. The side surface of the contact portion 32x is in contact with the interlayer insulating layer 60 and the gate electrode 30.

The IGBT 201 of the modified example can be manufactured, for example, in the method for manufacturing the semiconductor device of the second embodiment described above, by etching the gate electrode 30 when the opening 71 is defined in the first silicon oxide film 70.

According to the IGBT 201 of the modified example, for example, for example, a contact area between the contact portion 32x and the gate electrode 30 increases, and a contact resistance can be reduced.

As described above, according to the semiconductor device and the method for manufacturing the semiconductor device of the second embodiment and the modified example, it is possible to realize the semiconductor device that suppresses the warpage of the semiconductor wafer as in the first embodiment.

### Third Embodiment

The semiconductor device according to the third embodiment is different from the semiconductor device of the second embodiment in that the conductive layer to which the first portion is connected is not in the trench. Hereinafter, description of contents overlapping with the first embodiment or the second embodiment may be partially omitted.

The semiconductor device of the third embodiment is an IGBT 300. The IGBT 300 is a trench gate type IGBT including a gate electrode in a trench formed in a semiconductor layer.

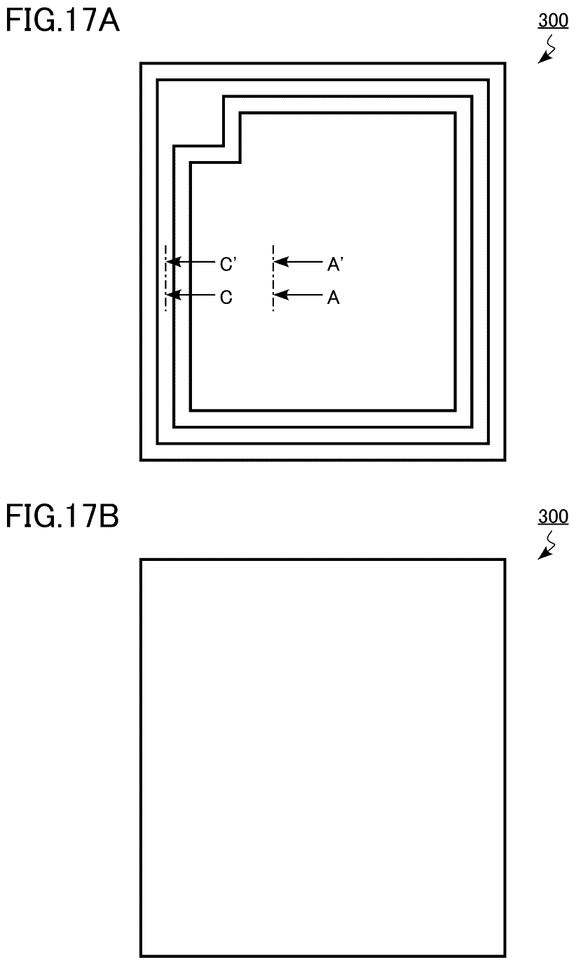

FIGS. 17A and 17B are schematic diagrams of the semiconductor device of the third embodiment. FIG. 17A is a front side view of the IGBT 300. FIG. 17B is a rear side view of the IGBT 300.

As illustrated in FIG. 17A, an emitter electrode 10, a gate electrode pad 31, and a gate electrode wiring 32 are provided on a front surface side of the IGBT 300. The gate electrode wiring 32 is connected to the gate electrode pad 31.

As illustrated in FIG. 17B, a collector electrode 20 is provided on a back surface side of the IGBT 300.

A plurality of transistors is provided under the emitter electrode 10. The gate electrode pad 31 and the gate electrode wiring 32 are electrically connected to the gate electrodes of the transistor. A gate voltage for controlling a switching operation of the transistors is applied to the gate electrode pad 31.

In the AA′ cross section of FIG. 17A, the IGBT 300 has, for example, the same structure as the IGBT 100 of the first embodiment shown in FIG. 2.

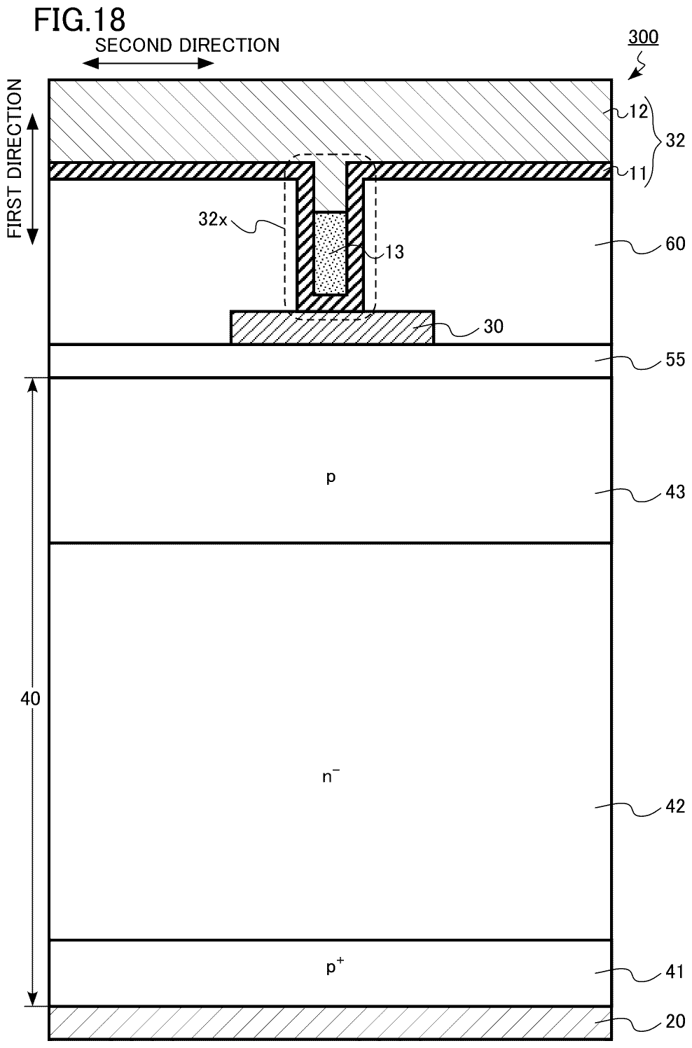

FIG. 18 is a schematic cross-sectional view of a part of the semiconductor device according to the third embodiment. FIG. 18 is a cross section taken along line CC′ in FIG. 17A.

The IGBT 300 according to the third embodiment includes the collector electrode 20 (second electrode), the gate electrode 30 (conductive layer), the gate electrode wiring 32 (first electrode), the semiconductor layer 40, the surface insulating layer 55 (first insulating layer), and the interlayer insulating layer 60 (second insulating layer).

The gate electrode wiring 32 includes the first metal layer 11, the second metal layer 12, and the insulator 13. The gate electrode wiring 32 includes the contact portion 32x (first portion).

In the semiconductor layer 40, the collector region 41, the drift region 42, and the base region 43 are provided.

Hereinafter, a direction connecting the gate electrode wiring 32 and the collector electrode 20 is referred to as the first direction. A direction orthogonal to the first direction is referred to as a second direction.

The semiconductor layer 40 is provided between the gate electrode wiring 32 and the collector electrode 20. The semiconductor layer 40 is in contact with the collector electrode 20.

The surface insulating layer 55 is provided on the surface of the semiconductor layer 40. The surface insulating layer 55 is provided between the gate electrode wiring 32 and the semiconductor layer 40. The surface insulating layer 55 is provided between the semiconductor layer 40 and the gate electrode 30. The surface insulating layer 55 is an example of the first insulating layer.

The surface insulating layer 55 is an insulating body. The surface insulating layer 55 is, for example, silicon oxide.

The gate electrode 30 is provided on the surface insulating layer 55. The gate electrode 30 is provided between the surface insulating layer 55 and the interlayer insulating layer 60. The gate electrode 30 is electrically connected to the gate electrode wiring 32 and the gate electrode pad 31. The gate electrode 30 is an example of the conductive layer.

The gate electrode 30 is a conductor. The gate electrode 30 is, for example, a semiconductor or a metal. The gate electrode 30 is, for example, amorphous silicon containing conductive impurities or polycrystalline silicon containing conductive impurities.

The interlayer insulating layer 60 is provided between the semiconductor layer 40 and the gate electrode wiring 32. The interlayer insulating layer 60 is provided between the surface insulating layer 55 and the gate electrode wiring 32. The interlayer insulating layer 60 is provided between the gate electrode 30 and the gate electrode wiring 32. The interlayer insulating layer 60 is an example of the second insulating layer.

The interlayer insulating layer 60 is an insulating body. The interlayer insulating layer 60 is, for example, silicon oxide.

The gate electrode wiring 32 is provided above the semiconductor layer 40. The gate electrode wiring 32 is provided on the interlayer insulating layer 60.

The gate electrode wiring 32 includes the first metal layer 11, the second metal layer 12, and the insulator 13. The second metal layer 12 is provided on the first metal layer 11. The first metal layer 11 is provided, for example, between the interlayer insulating layer 60 and the second metal layer 12.

The gate electrode wiring 32 includes the contact portion 32x. The contact portion 32x electrically connects the gate electrode wiring 32 and the gate electrode 30. The contact portion 32x is in contact with the gate electrode 30.

The contact portion 32x is provided between a part of the interlayer insulating layer 60 and another part of the interlayer insulating layer 60 in the cross section parallel to the first direction, for example, in the cross section illustrated in FIG. 18. In FIG. 18, the interlayer insulating layer 60 on the left side of the contact portion 32x corresponds to the part of the interlayer insulating layer 60, and the interlayer insulating layer 60 on the right side of the contact portion 32x corresponds to the another part of the interlayer insulating layer 60.

The contact portion 32x exists in an opening provided in the interlayer insulating layer 60. A bottom surface of the contact portion 32x is in contact with the gate electrode 30. A side surface of the contact portion 32x is in contact with the interlayer insulating layer 60.

The contact portion 32x includes the first metal layer 11, the second metal layer 12, and the insulator 13.

In the contact portion 32x, the first metal layer 11 is in contact with the gate electrode 30.

In the contact portion 32x, the insulator 13 is provided between the first metal layer 11 and the second metal layer 12. The insulator 13 is in contact with, for example, the first metal layer 11 and the second metal layer 12. The insulator 13 is surrounded by the first metal layer 11 and the second metal layer 12 in a cross section parallel to the first direction.

The first metal layer 11 is a conductor. The first metal layer contains, for example, a metal or a metal compound. The first metal layer contains at least one metal element selected from the group consisting of titanium (Ti), tantalum (Ta), nickel (Ni), tungsten (W), and molybdenum (Mo).

The second metal layer 12 is a conductor. The chemical composition of the second metal layer 12 is different from the chemical composition of the first metal layer 11, for example.

The second metal layer 12 contains, for example, a metal or a metal compound. The first metal layer contains, for example, aluminum (Al) or copper (Cu).

The insulator 13 is an insulating body. The insulator 13 includes, for example, an oxide, a nitride, or an oxynitride. The insulator 13 includes, for example, silicon oxide, silicon nitride, or silicon oxynitride.

The contact portion 32x has the same structure as the contact portion 10x of the first embodiment illustrated in FIG. 3 except that the bottom surface of the contact portion 32x is in contact with the gate electrode 30 instead of the semiconductor layer 40.

Next, an example of a method for manufacturing the semiconductor device according to the third embodiment will be described.

The method for manufacturing the semiconductor device according to the third embodiment is different from the method for manufacturing the semiconductor device of the second embodiment in that the conductive layer is not in the trench. Hereinafter, description of contents overlapping with those of the first embodiment or the second embodiment will be omitted.

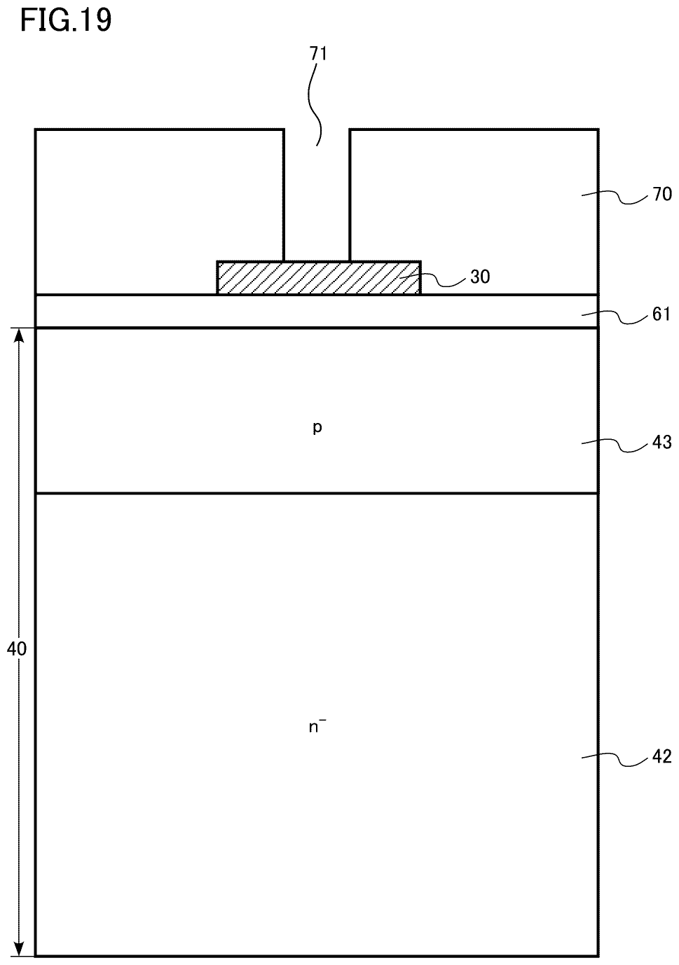

FIG. 19 is a view for explanation of the method for manufacturing the semiconductor device according to the third embodiment. FIG. 19 is a cross-sectional view corresponding to FIG. 18 of the third embodiment.

First, the drift region 42 and the base region 43 are formed in the semiconductor layer 40 using a known process technology. Next, a silicon oxide film 61 is formed on the semiconductor layer 40 using a known process technology.

Then, the gate electrode 30 is formed on the silicon oxide film 61. The gate electrode 30 is a conductive layer. The gate electrode 30 is an example of the first layer.

Next, the first silicon oxide film 70 is formed on the gate electrode 30. The first silicon oxide film 70 is formed by, for example, a chemical vapor deposition method (CVD method). The first silicon oxide film 70 is an example of the first insulating film. The first silicon oxide film 70 becomes the interlayer insulating layer 60 in the end.

Next, the opening 71 is defined in the first silicon oxide film 70 (FIG. 19). The opening 71 reaches the gate electrode 30. The gate electrode 30 is exposed at the bottom of the opening 71. The opening 71 is defined by using, for example, a lithography method and a reactive-ion etching method (RIE method).

After the opening 71 is defined, the IGBT 300 of the third embodiment illustrated in FIG. 18 is manufactured by a manufacturing method similar to the method for manufacturing the semiconductor device of the first embodiment.

As described above, according to the semiconductor device and the method for manufacturing the semiconductor device of the third embodiment, it is possible to realize the semiconductor device that suppresses the warpage of the semiconductor wafer as in the first embodiment.

In the first to third embodiments, the case where the semiconductor layer is single crystal silicon has been described as an example, but the semiconductor layer is not limited to single crystal silicon. For example, other single crystal semiconductors such as single crystal silicon carbide may be used.

In the first to third embodiments, the trench gate type IGBT has been described as an example of the semiconductor device, but the semiconductor device may be, for example, a planar gate type IGBT.

In the first to third embodiments, the IGBT has been described as an example of the semiconductor device, but the semiconductor device may be, for example, a metal oxide semiconductor field effect transistor (MOSFET), a diode, or an RC-IGBT in which an IGBT and a diode are provided on the same semiconductor chip.

In the second embodiment, the case where the conductive layer provided in the trench is the gate electrode has been described as an example, but the conductive layer provided in the trench may be, for example, a dummy gate electrode or a field plate electrode. When the conductive layer is a dummy gate electrode or a field plate electrode, the first electrode connected to the dummy gate electrode or the field plate electrode is, for example, the emitter electrode.

In the third embodiment, the case where the conductive layer is the gate electrode has been described as an example, but the conductive layer may be, for example, a dummy gate electrode or a field plate electrode. When the conductive layer is a dummy gate electrode or a field plate electrode, the first electrode connected to the dummy gate electrode or the field plate electrode is, for example, the emitter electrode.

In the third embodiment, the case where the conductive layer is the gate electrode has been described as an example, but the conductive layer is not limited to the gate electrode, and may be a different wiring layer.

In the first to third embodiments, the case where the first electrode is the emitter electrode or the gate electrode wiring has been described as an example, but the first electrode is not limited to the emitter electrode or the gate electrode wiring, and may be a different electrode or electrode wiring.

While certain embodiments have been described, these embodiments have been presented by way of example only, and are not intended to limit the scope of the inventions. Indeed, the semiconductor device and the method for manufacturing the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode including a first metal layer, a second metal layer, and an insulator;
a second electrode;
a semiconductor layer provided between the first electrode and the second electrode; and
an insulating layer provided between the first electrode and the semiconductor layer, wherein
the first electrode includes a first portion electrically connecting the semiconductor layer and the first electrode,
the first portion is provided between one part of the insulating layer and another part of the insulating layer in a cross section parallel to a first direction connecting the first electrode and the second electrode, and
the first portion includes the first metal layer in contact with the semiconductor layer, the second metal layer, and the insulator provided between the first metal layer and the second metal layer.

2. The semiconductor device according to claim 1, wherein
in the cross section, the insulator is surrounded by the first metal layer and the second metal layer.

3. The semiconductor device according to claim 1, wherein
the insulator contains one of an oxide, a nitride, and an oxynitride.

4. The semiconductor device according to claim 1, wherein
a chemical composition of the second metal layer is different from a chemical composition of the first metal layer.

5. The semiconductor device according to claim 1, wherein
the first metal layer contains tungsten (W), and the second metal layer contains aluminum (Al).

6. The semiconductor device according to claim 1, wherein
in the cross section, a part of a side surface of the first portion is in contact with the semiconductor layer.

7. The semiconductor device according to claim 1, wherein
in the cross section, a first thickness of the insulator of the first portion in the first direction is thicker than a second thickness of the first metal layer of a bottom surface of the first portion in the first direction.

8. The semiconductor device according to claim 1, wherein
in the cross section, a first thickness of the insulator of the first portion in the first direction is larger than a first width of the insulator of the first portion in a second direction perpendicular to the first direction.

9. The semiconductor device according to claim 1, wherein
in the cross section, a first width of the insulator of the first portion in a second direction perpendicular to the first direction is equal to or more than ½ of a second width of the first portion in the second direction.

10. The semiconductor device according to claim 1, wherein
in the cross section, a third thickness of the second metal layer of the first portion in the first direction is thicker than a second thickness of the first metal layer of a bottom surface of the first portion in the first direction.

11. The semiconductor device according to claim 1, wherein
in the cross section, a second thickness of the first metal layer of a bottom surface of the first portion in the first direction is thicker than a fourth thickness of the first metal layer of a side surface of the first portion in a second direction perpendicular to the first direction.

12. A semiconductor device comprising:
a first electrode including a first metal layer, a second metal layer, and an insulator;
a second electrode;
a semiconductor layer provided between the first electrode and the second electrode;
a first insulating layer provided between the first electrode and the semiconductor layer;
a second insulating layer provided between the first insulating layer and the first electrode; and
a conductive layer provided between the first insulating layer and the second insulating layer,
wherein
the first electrode includes a first portion connecting the conductive layer and the first electrode,
the first portion is provided between one part of the second insulating layer and another part of the second insulating layer in a cross section parallel to a first direction connecting the first electrode and the second electrode, and
the first portion includes the first metal layer in contact with the conductive layer, the second metal layer, and the insulator provided between the first metal layer and the second metal layer.

13. The semiconductor device according to claim 12, wherein
the semiconductor layer includes a trench,
the first insulating layer and the conductive layer are provided in the trench, and
the first metal layer is in contact with the conductive layer in the trench.

14. The semiconductor device according to claim 12, wherein
the conductive layer is polycrystalline silicon.

15. The semiconductor device according to claim 12, wherein
in the cross section, a part of a side surface of the first portion is in contact with the conductive layer.

16. A method for manufacturing a semiconductor device, the method comprising:
forming a first insulating film on a first layer being one of a semiconductor layer and a conductive layer;
forming an opening in the first insulating film;
forming a first metal film in the opening, the first metal film being in contact with the first layer;
forming a second insulating film on the first metal film, the second insulating film filling the opening;
removing the second insulating film around the opening; and
forming a second metal film on the first metal film, the second metal film being in contact with the first metal film and the second insulating film.

17. The method for manufacturing a semiconductor device according to claim 16, wherein
a part of the second insulating film remains in the opening in the removing the second insulating film.

18. The method for manufacturing a semiconductor device according to claim 16, wherein
a thickness of the second metal film is thicker than a thickness of the first metal film.

19. The method for manufacturing a semiconductor device according to claim 16, wherein
the second insulating film contains one of an oxide, a nitride, and an oxynitride.

20. The method for manufacturing a semiconductor device according to claim 16, wherein
a chemical composition of the second metal film is different from a chemical composition of the first metal film.
